(19) United States
(12) Patent Application Publication
(10) Pub. No.: US 2026/0109852 A1
(43) Pub. Date: Apr. 23, 2026

(54) RESIN COMPOSITION AND ARTICLE MADE THEREFROM

(71) Applicant: ELITE ELECTRONIC MATERIAL (KUNSHAN) CO., LTD., Kunshan City (CN)

(72) Inventors: Yan ZHANG, Kunshan City (CN); Rongtao WANG, Kunshan City (CN); Diya LIU, Kunshan City (CN); Yifan JIA, Kunshan City (CN)

(73) Assignee: ELITE ELECTRONIC MATERIAL (KUNSHAN) CO., LTD., Kunshan City (CN)

(21) Appl. No.: 19/000,095

(22) Filed: Dec. 23, 2024

(30) Foreign Application Priority Data
Oct. 22, 2024 (CN) 202411475629.1

(51) Int. Cl. C08L 71/12; C08F 212/08; C08F 222/06; C08F 236/06; C08F 236/16

(52) U.S. Cl. CPC C08L 71/12; C08F 212/08; C08F 222/06; C08F 236/06; C08F 236/16; C08L 2203/16; C08L 2203/20; C08L 2205/02; C08L 2205/03

(57) ABSTRACT

The present disclosure provides a resin composition comprising: a component (A): 100 parts by weight of polyphenylene ether resin containing unsaturated carbon-carbon double bonds; a component (B): 1 to 20 parts by weight of unhydrogenated maleic anhydride-modified first polyolefin; and a component (C): 5 to 100 parts by weight of benzocyclobutene-modified second polyolefin. Besides, the present disclosure also provides an article made from the resin composition. The article comprises a prepreg, a resin film, a laminate or a printed circuit board that has improvements in one or more properties including stability of peeling strength of bonding sheet and core, solder ball shear, bonding gap and solder floating delamination rate.

### CROSS-REFERENCE TO RELATED APPLICATIONS

This non-provisional application claims priority under 35 U.S.C. § 119 (a) on Patent Application No(s). 202411475629.1 filed in China on Oct. 22, 2024, the entire contents of which are hereby incorporated by reference.

### BACKGROUND

### 1. Technical Field

The present disclosure relates to a resin composition and an article made therefrom, particularly to a resin composition that can be applied to a prepreg, a resin film, a laminate (such as a copper-clad laminate) and a printed circuit board, and an article made therefrom.

### 2. Related Art

With the rapid development of electronic technology, the information processing of electronic products such as mobile communications, AI servers, and cloud storage is constantly advancing towards high-frequency and high-speed signal transmission. In order to meet the needs of high-frequency and high-speed information transmission, dielectric materials with excellent dielectric properties have become the key to the production of copper-clad laminates.

Hydrocarbon resin, such as polybutadiene and butadiene-styrene copolymer, have become mainstream materials in the industry due to their excellent dielectric properties. However, articles made from these hydrocarbon resins have defects such as poor stability of peeling strength of bonding sheet and core, small solder ball shear, gap presenting between the glass fabric and the resin composition, and high solder floating delamination rate. The present disclosure is intended to provide a new resin composition that solves one or more of the defects mentioned above.

### SUMMARY

In view of the above problems in the prior arts, specifically, the current material is unable to meet one or more of the technical demands, the main purpose of the present disclosure is to provide a resin composition and an article made from the resin composition comprising a prepreg, a resin film, a laminate or a printed circuit board that solves one or more of the above problems.

In one aspect, the present disclosure provides a resin composition, including:
a component (A): 100 parts by weight of an unsaturated carbon-carbon double bond-containing polyphenylene ether resin;
a component (B): 1 to 20 parts by weight of an unhydrogenated maleic anhydride-modified first polyolefin; and
a component (C): 5 to 100 parts by weight of a benzocyclobutene-modified second polyolefin.

In one aspect, the present disclosure also provides an article made from the resin composition, and the article includes a prepreg, a resin film, a laminate or a printed circuit board.

The resin composition or the article made therefrom provided by the present disclosure have improvements in one or more properties including stability of peeling strength of bonding sheet and core, solder ball shear, bonding gap, and solder floating delamination rate.

### DETAILED DESCRIPTION

The features and advantages of the present disclosure are described in detail in the following embodiments, and the contents are sufficient to enable any person skilled in the art to understand the technical content of the present disclosure and implement it accordingly. According to the specification, the claim and the drawings, any person skilled in the art can easily understand the relevant purposes and advantages of the present disclosure. The following embodiments further explain the viewpoints of the present disclosure in detail, but do not limit the scope of the present disclosure in any viewpoint.

The terms used herein may be commonly used terms in the relevant field, and the terms used herein should not be understood as limiting the present disclosure, but should be understood as examples of terms used to describe the embodiments. In the case of conflict, the definitions contained herein shall prevail.

Unless otherwise specified, the components or technical features of the present disclosure described in the singular form also include the plural form.

The terms “comprise,” “include,” “contain,” “have,” or the like used herein belong to open-ended transitional phrase. Unless otherwise specified, other parts may also be included when using the terms. The terms “consisting of,” “composed by,” “remainder being,” or the like used herein belong to close-ended transitional phrase.

The phrase “a composition comprises A, B, and C, wherein A comprises a1, a2, or a3” has the same meaning as the phrase “a composition comprises A, B, and C, wherein A comprises a1, a2, a3, or a combination thereof,” that is, “a composition comprises A, B, and C, wherein A comprises a1, a2, a3, a combination of a1 and a2, a combination of a1 and a3, a combination of a2 and a3, or a combination of a1, a2, and a3.” The phrase “or a combination thereof” used herein is the same as “or any combination thereof”.

For the convenience of the description, numerical ranges used herein shall be understood as including all of the possible subranges and individual values therein, including integers and decimals.

The value used herein includes all of the values which will be the same as such value after being rounded off.

It should be understood that members in the Markush group can individually or combinely be used to describe the present disclosure.

Unless otherwise specified, the term “monomer” used herein refers to a molecule that can be covalently linked to the same or other molecules to form a polymer.

Unless otherwise specified, the term “polymer” used herein refers to products formed by monomer(s) via polymerization. A polymer may include a homopolymer, a copolymer, a prepolymer, etc., but the present disclosure is not limited thereto. A prepolymer refers to a polymer with a lower molecular weight having a degree of polymerization between that of a monomer and that of a final polymer. A polymer includes an oligomer, but the present disclosure is not limited thereto. An oligomer, also known as low polymer, refers to a polymer formed by 2 to 20, typically 2 to 5, repeating units. For instance, diene polymer includes diene homopolymer, diene copolymer, diene prepolymer, and diene oligomer.

Unless otherwise specified, the term “copolymer” used herein refers to a product formed by two or more different monomers via polymerization, including random copolymers, alternating copolymers, graft copolymers, or block copolymers, but the present disclosure is not limited thereto. For instance, a styrene-butadiene copolymer is a product formed by only styrene and butadiene monomers via polymerization. For instance, the styrene-butadiene copolymer includes a styrene-butadiene random copolymer, a styrene-butadiene alternating copolymer, a styrene-butadiene graft copolymer, or a styrene-butadiene block copolymer, but the present disclosure is not limited thereto. For instance, the styrene-butadiene block copolymer includes a styrene-butadiene diblock copolymer and a styrene-butadiene-styrene triblock copolymer, but the present disclosure is not limited thereto. Similarly, a hydrogenated styrene-butadiene copolymer includes a hydrogenated styrene-butadiene random copolymer, a hydrogenated styrene-butadiene alternating copolymer, a hydrogenated styrene-butadiene graft copolymer, or a hydrogenated styrene-butadiene block copolymer. For instance, the hydrogenated styrene-butadiene block copolymer includes a hydrogenated styrene-butadiene diblock copolymer and a hydrogenated styrene-butadiene-styrene triblock copolymer, but the present disclosure is not limited thereto.

It should be understood that a resin composition containing three compounds A, B, and C and an additive (four components in total) and a resin composition containing a prepolymer formed by three compounds A, B, and C and an additive (two components in total) are different resin compositions. There are significant differences between the two resin compositions in terms of preparation methods, physicochemical properties and the properties of products made therefrom. The former directly mixes compounds A, B, C and the additive, while the latter requires compounds A, B, C to be prepolymerized under appropriate conditions to generate prepolymers, and then mixed with the additive. Since the function of the prepolymer in the resin composition is different from the function of compounds A, B, C alone or together in the resin composition, the two resin compositions should be regarded as different chemical substances with different chemical properties. For instance, when the resin composition is heated to a semi-cured state, the latter presents a partial cross-linking reaction between the prepolymer and the cross-linking agent, rather than compounds A, B, and C reacting with the cross-linking agent separately, so the properties of the articles are completely different.

Unless otherwise specified, the term “resin” used herein should be understood as including a monomer, a polymer thereof, a combination of the monomer, a combination of the polymer, or a combination of the monomer and the polymer, but the present disclosure is not limited thereto. For instance, the term “maleimide resin” used herein includes a maleimide monomer, a maleimide polymer, a combination of the maleimide monomer, a combination of the maleimide polymer, or a combination of the maleimide monomer and the maleimide polymer.

Unless otherwise specified, the term “modification” used herein includes a product derived from a resin with its reactive functional group modified, a product derived from a prepolymerization reaction of a resin and other resins, a product derived from copolymerizing a resin and other resins, and a product derived from a crosslinking reaction of a resin and other resins, etc.

Unless otherwise specified, the term “unsaturated bond” used herein refers to a reactive unsaturated bond, such as an unsaturated double bond with the potential of being crosslinked with other functional groups, such as an unsaturated carbon-carbon double bond with the potential of being crosslinked with other functional groups, but the present disclosure is not limited thereto.

The term “unsaturated carbon-carbon double bond” used herein includes a vinyl group, a vinylbenzyl group, a (meth)acryloyl group, an allyl group or a combination thereof, but the present disclosure is not limited thereto. A vinyl group should be understood as including a vinyl group and a vinylidene group, and a (meth)acryloyl should be understood as including a acryloyl group and a methacryloyl group. Therefore, unless otherwise specified, the unsaturated carbon-carbon double bond-containing polyphenylene ether resin used herein includes the polyphenylene ether resin having any one of a vinyl group, a vinylbenzyl group, a (meth)acryloyl group, an allyl group, but the present disclosure is not limited thereto.

Unless otherwise specified, any compound used herein includes various isomers thereof. For instance, a propyl group should be understood as including isopropyl and n-propyl.

Unless otherwise specified, the term “part(s) by weight” used herein represents weight part(s) in any weight unit, such as kilogram, gram, pound, but the present disclosure is not limited thereto. For instance, 100 parts by weight of the unsaturated carbon-carbon double bond-containing polyphenylene ether resin may represent 100 kilograms of the unsaturated carbon-carbon double bond-containing polyphenylene ether resin or 100 pounds of the unsaturated carbon-carbon double bond-containing polyphenylene ether resin. If the resin solution includes a solvent and a resin, the parts by weight of the (solid or liquid) resin generally refers to the weight unit of the (solid or liquid) resin and does not include the weight unit of the solvent in the solution, while the parts by weight of the solvent refers to the weight unit of the solvent.

It should be understood that the features of various embodiments of the present invention may be partially or entirely combined with each other.

It should be understood that the following embodiments are illustrative in all aspects and do not limit the present disclosure, and are intended to explain the scope of the technical concept of the present disclosure. Therefore, the scope of the present disclosure is not limited to the disclosed embodiments.

The present disclosure provides a resin composition, including:
a component (A): 100 parts by weight of an unsaturated carbon-carbon double bond-containing polyphenylene ether resin;
a component (B): 1 to 20 parts by weight of an unhydrogenated maleic anhydride-modified first polyolefin; and
a component (C): 5 to 100 parts by weight of a benzocyclobutene-modified second polyolefin.

In one embodiment, for instance, the unhydrogenated maleic anhydride-modified first polyolefin includes a maleic anhydride-adducted polybutadiene, a maleic anhydride-adducted polyisoprene, a maleic anhydride-adducted styrene-butadiene copolymer, a maleic anhydride-adducted styrene-isoprene copolymer or a combination thereof. These components should be understood as including modifications or derivatives thereof. The unhydrogenated maleic anhydride-modified first polyolefin has unsaturated carbon-carbon double bonds.

In one embodiment, for instance, the benzocyclobutene-modified second polyolefin includes any one of a benzocyclobutene-modified heteroatom-containing polyolefin, a benzocyclobutene-modified non-heteroatom-containing polyolefin or a combination thereof.

In one embodiment, for instance, the heteroatom-containing polyolefin includes any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer, a vinyl-polybutadiene-urethane polymer, a silane-modified styrene-butadiene copolymer, an acryloyl group-terminated polybutadiene, an epoxy group-containing polybutadiene or a combination thereof. These components should be understood as including modifications or derivatives thereof.

In one embodiment, for instance, the non-heteroatom-containing polyolefin includes any one of a polybutadiene, a polyisoprene, a styrene-butadiene copolymer, a styrene-isoprene copolymer, a styrene-butadiene-divinylbenzene polymer, a styrene-ethylene-divinylbenzene polymer, a styrene-ethylvinylbenzene-divinylbenzene polymer or a combination thereof. These components should be understood as including modifications or derivatives thereof.

In one embodiment, for instance, the mass ratio of the benzocyclobutene-modified non-heteroatom-containing polyolefin to the benzocyclobutene-modified heteroatom-containing polyolefin is preferably 2:3 to 24:1.

Unless otherwise specified, the amount of each component in the resin composition of the present disclosure is calculated based on the amount of the unsaturated carbon-carbon double bond-containing polyphenylene ether resin being 100 parts by weight. For instance, with respect to 100 parts by weight of the unsaturated carbon-carbon double bond-containing polyphenylene ether resin, the amount of the unhydrogenated maleic anhydride-modified first polyolefin is 1 to 20 parts by weight, such as 1 part by weight, 5 parts by weight, 8 parts by weight, 10 parts by weight, 12 parts by weight, 15 parts by weight, 20 parts by weight; with respect to 100 parts by weight of the unsaturated carbon-carbon double bond-containing polyphenylene ether resin, the amount of the benzocyclobutene-modified second polyolefin is 5 to 100 parts by weight, such as 5 parts by weight, 20 parts by weight, 40 parts by weight, 50 parts by weight, 60 parts by weight, 80 parts by weight, 100 parts by weight, but the present disclosure is not limited thereto.

The unsaturated carbon-carbon double bond-containing polyphenylene ether resin of the present disclosure may be one or more of the unsaturated carbon-carbon double bond-containing polyphenylene ether resin that may be applied to manufacturing a prepreg, a resin film, a laminate or a printed circuit board, and may be one or more of commercially available products, self-made products or a combination thereof, such as any one of a vinylbenzyl group-containing polyphenylene ether resin, a (meth)acryloyl group-containing polyphenylene ether resin, a vinyl group-containing polyphenylene ether resin, a allyl group-containing polyphenylene ether resin or a combination thereof, but the present disclosure is not limited thereto.

The unsaturated carbon-carbon double bond-containing polyphenylene ether resin of the present disclosure has unsaturated carbon-carbon double bonds and a phenyl ether backbone. The unsaturated carbon-carbon double bonds act as reactive functional groups, which upon heating, can undergo self-polymerization or undergo free radical polymerization with other components in the resin composition that have unsaturated bonds, and ultimately being crosslinked and cured. The cured product has properties of high thermal resistance and low dielectic. Preferably, the unsaturated carbon-carbon double bond-containing polyphenylene ether resin includes the unsaturated carbon-carbon double bond-containing polyphenylene ether resin where the phenyl ether backbone is substituted with 2,6-dimethyl groups. The methyl substitution results in steric hindrance, making it difficult for the oxygen atom of the ether to form hydrogen bonds or van der Waals forces, thereby reducing moisture absorption and resulting in better dielectric properties.

In one embodiment, for instance, the unsaturated carbon-carbon double bond-containing polyphenylene ether resin includes a vinylbenzyl group-containing polyphenylene ether resin with a number average molecular weight of about 1200 (such as OPE-2st 1200, available from Mitsubishi Gas Chemical Co., Inc.), a vinylbenzyl group-containing polyphenylene ether resin with a number average molecular weight of about 2200 (such as OPE-2st 2200, available from Mitsubishi Gas Chemical Co., Inc.), a vinylbenzyl group-containing polyphenylene ether resin with a number average molecular weight of about 2400 to 2800 (such as vinylbenzyl group-containing bisphenol A polyphenylene ether resin), a (meth)acryloyl group-containing polyphenylene ether resin with a number average molecular weight of about 1900 to 2300 (such as SA9000, available from Sabic company), a vinyl group-containing polyphenylene ether resin with a number average molecular weight of about 2200 to 3000 or a combination thereof, but the present disclosure is not limited thereto. Among them, the vinyl group-containing polyphenylene ether resin may include various polyphenylene ether resins disclosed in the US Patent Application Publication No. 2016/0185904 A1, all of which are incorporated herein by reference in their entirety. For instance, in one embodiment, the vinylbenzyl group-containing polyphenylene ether resin includes a vinylbenzyl group-containing biphenyl polyphenylene ether resin, a vinylbenzyl group-containing bisphenol A polyphenylene ether resin or a combination thereof, but the present disclosure is not limited thereto.

In one embodiment, for instance, any one of a polyolefin different from the component (B) and the component (C), an unsaturated carbon-carbon double bond-containing crosslinking agent, a organosilicon resin, a benzoxazine resin, an epoxy resin, a polyester resin, a phenol resin, an amine curing agent, a polyamide, a polyimide, a styrene maleic anhydride, a maleimide resin, a cyanate ester resin, a maleimide triazine resin or a combination thereof may be added to the resin composition of the present disclosure as needed.

Unless otherwise specified, in the resin composition of the present disclosure, with respect to 100 parts by weight of the unsaturated carbon-carbon double bond-containing polyphenylene ether resin, the amount of the polyolefin different form the component (B) and the component (C), the unsaturated carbon-carbon double bond-containing crosslinking agent, the organosilicon resin, the benzoxazine resin, the epoxy resin, the polyester resin, the phenol resin, the polyamide, the polyimide, the styrene maleic anhydride, the maleimide resin, the cyanate ester resin, the maleimide triazine resin may be adjusted as needed. For instance, each component may independently be 1 part by weight to 100 parts by weight, such as 1 part by weight, 5 parts by weight, 10 parts by weight, 15 parts by weight, 20 parts by weight, 25 parts by weight, 50 parts by weight or 100 parts by weight, but the present disclosure is not limited thereto. For instance, with respect to 100 parts by weight of the unsaturated carbon-carbon double bond-containing polyphenylene ether resin, the amount of the amine curing agent may be adjusted as needed. For instance, the amount of the amine curing agent may be 1 part by weight to 30 parts by weight, but the present disclosure is not limited thereto.

The polyolefin different from the component (B) and the component (C) of the present disclosure may be a polyolefin different from the component (B) and the component (C) that may be applied to manufacturing a prepreg, a resin film, a laminate or a printed circuit board, and may be one or more of commercially available products, self-made products or a combination thereof. The polyolefin different from the component (B) and the component (C) of the resin composition of the present disclosure includes any one of a polybutadiene, a polyisoprene, a styrene-butadiene copolymer, a styrene-isoprene copolymer, a styrene-butadiene-divinylbenzene polymer, a vinyl-polybutadiene-urethane polymer, a polymethyl styrene, a hydrogenated polybutadiene, a hydrogenated polyisoprene, a hydrogenated styrene-butadiene-divinylbenzene polymer, a hydrogenated maleic anhydride-adducted polybutadiene, a hydrogenated maleic anhydride-adducted styrene-butadiene polymer, a hydrogenated styrene-butadiene copolymer, a hydrogenated styrene-isoprene copolymer, a styrene-ethylene-divinylbenzene polymer, a styrene-ethylvinylbenzene-divinylbenzene polymer or a combination thereof, but the present disclosure is not limited thereto.

The unsaturated carbon-carbon double bond-containing crosslinking agent of the resin composition of the present disclosure is any one of a bis(vinylphenyl)ethane(BVPE), a divinylbenzene (DVB), a divinylnaphthalene, a divinylbiphenyl, triallyl isocyanurate (TAIC), a triallyl cyanurate (TAC), a vinylbenzocyclobutene (VBCB), a bis(vinylbenzyl)ether (BVBE), a trivinyl cyclohexane (TVCH), a diallyl bisphenol A (DABPA), a butadiene, a decadiene, an octadiene or a combination thereof.

In the present disclosure, for instance, the organosilicon resin may be various organosilicon resins known in the field, including a polyalkyl organosilicon resin, a polyaryl organosilicon resin, a polyalkylaryl organosilicon resin, a modified organosilicon resin or a combination thereof. The modified organosilicon resin includes an amino group-modified organosilicon resin, an epoxy group-modified organosilicon resin, a methacryloyl group-modified organosilicon resin, a hydroxyl group-modified organosilicon resin, a carboxyl group-modified organosilicon resin or a combination thereof, but the present disclosure is not limited thereto. Preferably, for instance, the amino group-modified organosilicon resin of the present disclosure may be amino group-modified organosilicon resin products KF-8010, X-22-161A, X-22-161B, KF-8012, KF-8008, X-22-9409, X-22-1660B-3 available from Shin-Etsu Chemical Co., Ltd., BY-16-853U, BY-16-853, BY-16-853B available from Toray-Dow corning Co., Ltd., XF42-C5742, XF42-C6252, XF42-C5379 available from Momentive Performance Materials JAPAN LLC or a combination thereof. For instance, the epoxy group-modified organosilicon resin of the present disclosure may be products of X-22-163 series available from Shin-Etsu Chemical Co., Ltd. For instance, the methacryloyl group-modified organosilicon resin of the present disclosure may be products of X-22-164 series available from Shin-Etsu Chemical Co., Ltd.

In the present disclosure, for instance, the benzoxazine resin may be various benzoxazine resins known in the field, including bisphenol A benzoxazine resin, a bisphenol F benzoxazine resin, a phenolphthalein benzoxazine resin, a dicyclopentadiene benzoxazine resin, a phosphorus-containing benzoxazine resin, a diamine benzoxazine resin and a phenyl-modified, vinyl group-modified or allyl-modified benzoxazine resin, but the present disclosure is not limited thereto. The suitable commercial products include products LZ-8270 (phenolphthalein benzoxazine resin), LZ-8298 (phenolphthalein benzoxazine resin), LZ-8280 (bisphenol F benzoxazine resin), LZ-8290 (bisphenol A benzoxazine resin) available from Huntsman, or products KZH-5031 (vinyl group-modified benzoxazine resin), KZH-5032 (phenyl-modified benzoxazine resin) available from Kolon Industries. Among them, the diamine benzoxazine resin may be a diaminodiphenylmethane benzoxazine resin, a diaminodiphenyl ether benzoxazine resin, a diaminodiphenyl sulfone benzoxazine resin, a diaminodiphenyl sulfide benzoxazine resin or a combination thereof, but the present disclosure is not limited thereto.

In the present disclosure, for instance, the epoxy resin may be various epoxy resins known in the field. For improving the thermal resistance of the resin composition, the epoxy resin includes any one of a bisphenol A epoxy resin, a bisphenol F epoxy resin, a bisphenol S epoxy resin, a bisphenol AD epoxy resin, a novolac epoxy resin, a trifunctional epoxy resin, a tetrafunctional epoxy resin, a multifunctional novolac epoxy resin, dicyclopentadiene (DCPD) epoxy resin, a phosphorus-containing epoxy resin, a p-xylene epoxy resin, a naphthalene epoxy resin (such as naphthol epoxy resin), a benzofuran epoxy resin, a isocyanate-modified epoxy resin or a combination thereof, but the present disclosure is not limited thereto. In the present disclosure, for instance, the novolac epoxy resin may be a phenol novolac epoxy resin, a bisphenol A novolac epoxy resin, a bisphenol F novolac epoxy resin, a biphenyl novolac epoxy resin, a phenol benzaldehyde epoxy resin, a phenol aralkyl novolac epoxy resin or a o-cresol novolac epoxy resin. In the present disclosure, for instance, the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be one or more selected from DOPO-containing phenol novolac epoxy resin, DOPO-containing o-cresol novolac epoxy resin and DOPO-containing bisphenol-A novolac epoxy resin. The DOPO-HQ epoxy resin may be one or more selected from DOPO-HQ-containing phenol novolac epoxy resin, DOPO-HQ-containing o-cresol novolac epoxy resin and DOPO-HQ-containing bisphenol-A novolac epoxy resin, but the present disclosure is not limited thereto.

In the present disclosure, for instance, the polyester resin may be various polyester resins known in the field, including a dicyclopentadiene-containing polyester resin, a biphenyl-containing polyester resin and a naphthalene-containing polyester resin, but the present disclosure is not limited thereto. The polyester resin includes products HPC-8000, HPC-8800 or HPC-8150 available from D.I.C. Corporation, but the present disclosure is not limited thereto.

In the present disclosure, for instance, the phenol resin may be various phenol resins known in the field, including a novolac resin or a phenoxy resin, wherein the novolac resin includes a phenol novolac resin, an o-cresol novolac resin, a bisphenol A novolac resin, a naphthol novolac resin, a biphenyl novolac resin and a dicyclopentadiene phenol resin, but the present disclosure is not limited thereto.

In the present disclosure, for instance, the amine curing agent may be various amine curing agents known in the field, including at least one of a diaminodiphenyl sulfone, a diaminodiphenylmethane, a diaminodiphenyl ether, a diaminodiphenyl sulfide and a dicyandiamide or a combination thereof, but the present disclosure is not limited thereto.

In the present disclosure, for instance, the polyamide may be various polyamides known in the field, including any commercially available polyamide resin products, but the present disclosure is not limited thereto.

In the present disclosure, for instance, the polyimide may be various polyimides known in the field, including any commercially available polyimide resin products, but the present disclosure is not limited thereto.

In the present disclosure, for instance, the styrene maleic anhydride may be various styrene maleic anhydrides known in the field, and the ratio of styrene (St) to maleic anhydride (MA) may be 1/1, 2/1, 3/1, 4/1, 6/1, 8/1 or 12/1. The example includes styrene maleic anhydride copolymer products SMA-1000, SMA-2000, SMA-3000, EF-30, EF-40, EF-60 and EF-80 available from Cray Valley, or styrene maleic anhydride copolymer products C400, C500, C700, C900 available from Polyscope, but the present disclosure is not limited thereto.

In the present disclosure, for instance, the maleimide resin maybe various maleimide resins known in the field, including 4,4′-diphenylmethane bismaleimide), polyphenylmethane maleimide (or oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane), N-2,3-xylylmaleimide, N-2,6-xylylmalcimide, N-phenylmaleimide, vinyl benzyl maleimide (VBM), biphenyl group-containing maleimide, isopropyl and meta-arylene structure-containing maleimide, indane-containing maleimide, maleimide resin with aliphatic structure having 10 to 50 carbon atoms, prepolymer of diallyl compounds and maleimide resins, prepolymer of diamines and maleimide resins, prepolymer of multifunctional amines and maleimide resins, prepolymers of acidic phenol compounds and maleimide resins or a combination thereof, but the present disclosure is not limited thereto. These components should be understood as including modifications thereof.

For instance, the maleimide resin includes maleimide resin products BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H available from Daiwakasci Industry Co., Ltd., or maleimide resin products BMI-70 or BMI-80 available from K.I Chemical Co., Ltd., maleimide resin products MIR-3000 or MIR-5000 available from Nippon Kayaku, indane-containing maleimide resins available from DIC, but the present disclosure is not limited thereto.

For instance, the maleimide resin with an aliphatic structure having 10 to 50 carbon atoms (or imide-extended maleimide resin) may include various imide-extended maleimide resins disclosed in the Taiwan Patent Application Publication No. 200508284A, all of which are incorporated herein by reference in their entirety, but the present disclosure is not limited thereto. The maleimide resin with an aliphatic structure having 10 to 50 carbon atoms of the present disclosure may include maleimide resin products BMI-689, BMI-1400, BMI-1500, BMI-1700, BMI-2500, BMI-3000, BMI-5000 and BMI-6000 available from Designer Molecules Inc., but the present disclosure is not limited thereto.

In the present disclosure, for instance, the cyanate ester may be various cyanate ester resins known in the field, such as a compound having a structure of Ar—O—C≡N, where the Ar may be a substituted or unsubstituted aromatic group. For improving the thermal resistance of the resin composition, the cyanate ester includes a novolac cyanate ester resin, a bisphenol A cyanate ester resin, a bisphenol F cyanate ester resin, a dicyclopentadiene-containing cyanate ester resin, a naphthalene-containing cyanate ester resin, a phenolphthalein cyanate ester resin, an adamantane cyanate ester resin, a fluorene cyanate ester resin or a combination thereof, but the present disclosure is not limited thereto. Among them, the novolac cyanate ester resin may be a bisphenol A novolac cyanate ester resin, a bisphenol F novolac cyanate ester resin or a combination thereof. For instance, the cyanate ester resin may be cyanate ester resin products Primaset PT-15, PT-30S, PT-60S, BA-200, BA-230S, BA-3000S, BTP-2500, BTP-6020S, DT-4000, DT-7000, ULL950S, HTL-300, CE-320, LVT-50, LeCy available from Lonza.

In the present disclosure, for instance, the maleimide triazine resin may be various maleimide triazine resins known in the field, including a maleimide triazine resin obtained by polymerizing a maleimide resin and a bisphenol A cyanate ester resin, a maleimide triazine resin obtained by polymerizing a maleimide resin and a bisphenol F cyanate ester resin, a maleimide triazine resin obtained by polymerizing a maleimide resin and a phenol novolac cyanate ester resin, a maleimide triazine resin obtained by polymerizing a maleimide resin and a dicyclopentadiene-containing cyanate ester resin, but the present disclosure is not limited thereto. In one embodiment, the maleimide triazine resin may be obtained by polymerizing the maleimide resin and the cyanate ester resin mentioned above in any molar ratio, for instance, the molar ratio of maleimide resin to cyanate ester resin may be 1:1 to 1:10, such as 1:1, 1:2, 1:4, 1:6, 1:8, 1:10, but the present disclosure is not limited thereto.

In one embodiment, for instance, the resin composition further includes a curing accelerator, a polymerization inhibitor, a flame retardant, an inorganic filler, a surfactant, a coloring agent, a toughening agent, a solvent or a combination thereof.

In the present disclosure, for instance, the curing accelerator (including a curing initiator) may include a catalyst, such as a Lewis base or a Lewis acid. The Lewis base may include one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may include metal salt compounds, such as metal salt compounds of manganese, iron, cobalt, nickel, copper and zinc, such as zinc octanoate or cobalt octanoate. The curing accelerator also includes a curing initiator, such as a peroxide capable of producing free radicals. The curing initiator includes dicumyl peroxide (DCP), tert-butyl perbenzoate, dibenzoyl peroxide (BPO), 2,5-dimethyl-2,5-di(tert-butylperoxy)-3-hexyne (25B), bis(tert-butylperoxyisopropyl)benzene or a combination thereof, but the present disclosure is not limited thereto. For instance, in one embodiment, with respect to 100 parts by weight of the unsaturated carbon-carbon double bond-containing polyphenylene ether resin, the resin composition of the present disclosure may further include 0.01 parts by weight to 5.0 parts by weight of the curing accelerator, preferably 0.01 parts by weight to 4.0 parts by weight of the curing accelerator, more preferably 0.1 parts by weight to 3.0 parts by weight of the curing accelerator, but the present disclosure is not limited thereto.

In the present disclosure, for instance, the polymerization inhibitor may include 1,1-diphenyl-2-picrylhydrazyl radical, methyl acrylonitrile, nitroxide-mediated radical, triphenylmethyl radical, metal ion radical, sulfur radical (such as dithioester), hydroquinone, p-methoxyphenol, p-benzoquinone, phenothiazine, β-phenylnaphthylamine, p-tert-butylcatechol, methylene blue, 4,4′-butylidenebis(6-tert-butyl-3-methylphenol), 2,2′-methylenebis(4-ethyl-6-t-butylphenol) or a combination thereof, but the present disclosure is not limited thereto. For instance, the nitroxide-mediated radical may include nitroxide radicals derived from cyclic hydroxylamines, such as 2,2,6,6-substituted piperidine 1-oxyl free radical or 2,2,5,5-substituted pyrrolidine 1-oxyl free radical. As a substituent, the alkyl group having less than 4 carbon atoms, such as a methyl group or an ethyl group, is preferred, but the present disclosure is not limited thereto. The nitroxide-mediated radical includes 2,2,6,6-tetramethylpiperidin-1-oxyl free radical, 2,2,6,6-tetraethylpiperidin-1-oxyl free radical, 2,2,6,6-tetramethyl-4-oxopiperidin-1-oxyl free radical, 2,2,5,5-tetramethylpyrrolidine-1-oxyl free radical, 1,1,3,3-tetramethyl-2-isoindoline-2-oxygen free radical, N,N-di-tert-butylamine oxygen free radical or the like, but the present disclosure is not limited thereto. The nitroxide radicals may also be replaced by using stable radicals such as galvinoxyl radicals. The polymerization inhibitor of the resin composition of the present disclosure may also be products derived from the polymerization inhibitor with its hydrogen atom or group substituted by other atom or group, such as products derived from a polymerization inhibitor with its hydrogen atom substituted by an amino group, a hydroxyl group, a ketocarbonyl group or the like. For instance, in one embodiment, based on 100 parts by weight of the unsaturated carbon-carbon double bond-containing polyphenylene ether resin, the resin composition of the present disclosure may further include 0.001 parts by weight to 20 parts by weight of the polymerization inhibitor, preferably 0.01 parts by weight to 10 parts by weight of the polymerization inhibitor, but the present disclosure is not limited thereto.

In the present disclosure, for instance, the flame retardant may be one or more of the flame retardant that may be applied to manufacturing a prepreg, a resin film, a laminate or a printed circuit board, including a phosphorus-containing flame retardant or a bromine-containing flame retardant. The bromine-containing flame retardant preferably includes decabromodiphenylethane, but the present disclosure is not limited thereto. The phosphorus-containing flame retardant preferably includes hydroquinone bis-(diphenyl phosphate), bisphenol A bis-(diphenylphosphate), tri (2-carboxyethyl) phosphine (TCEP), trimethyl phosphate (TMP), dimethyl methyl phosphonate (DMMP), resorcinol bis(dixylenyl phosphate), RDXP (such as products PX-200, PX-201 and PX-202), ammonium polyphosphate, melamine polyphosphate, phosphazene (such as products SPB-100, SPH-100, SPV-100), 9,10-dihydro-9-oxa-10-phosphaphenanthrene-10-oxide (DOPO) and its derivatives (such as di-DOPO compounds) or resins, diphenylphosphine oxide (DPPO) and its derivatives (such as di-DPPO compounds) or resins, melamine cyanurate, tri-hydroxy ethyl isocyanurate, aluminium phosphinate (such as products OP-930 and OP-935) or a combination thereof.

In the present disclosure, for instance, the flame retardant may be a flame retardant available from Katayama Chemical Industries Co., Ltd., including V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S or C-11R, but the present disclosure is not limited thereto. The flame retardant of the present disclosure may include one or more of the flame retardant above.

For instance, in one embodiment, with respect to 100 parts by weight of the unsaturated carbon-carbon double bond-containing polyphenylene ether resin, the resin composition of the present disclosure may further include 1 part by weight to 100 parts by weight of the flame retardant, preferably 5 parts by weight to 50 parts by weight of the flame retardant.

In the present disclosure, for instance, the inorganic filler may be one or more of the inorganic filler that may be applied to manufacturing a prepreg, a resin film, a laminate or a printed circuit board, including silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof, but the present disclosure is not limited thereto. In addition, the inorganic filler may be spherical (including solid sphere or hollow sphere), fibrous, plate-like, particulate, flake-like or whisker-like, and may be optionally pretreated by a silane coupling agent. In addition, the inorganic filler may be prepared by various methods, such as a melting method, a combustion method, or a chemical synthesis method. In addition, the particle size of the inorganic filler is not particularly limited, and the median particle size D50 may be 1 μm to 45 μm, preferably 1 μm to 15 μm, more preferably 1 μm to 10 μm. For instance, in one embodiment, with respect to 100 parts by weight of the unsaturated carbon-carbon double bond-containing polyphenylene ether resin, the resin composition of the present disclosure may further include 10 parts by weight to 300 parts by weight of the inorganic filler, preferably 50 parts by weight to 300 parts by weight of the inorganic filler, more preferably 75 parts by weight to 300 parts by weight of the inorganic filler, but the present disclosure is not limited thereto.

In the present disclosure, for instance, the surfactant may include silane (such as siloxane), and based on the functional group, the silane may be divided into amino silane, epoxide silane, vinyl silane, ester silane, hydroxyl silane, isocyanate silane, methacryloyloxyl silane and acryloyloxyl silane. The main function of adding the surfactant in the present disclosure is to make the inorganic filler uniformly disperse in the resin composition, but the present disclosure is not limited thereto. For instance, in one embodiment, with respect to 100 parts by weight of the unsaturated carbon-carbon double bond-containing polyphenylene ether resin, the resin composition of the present disclosure may further include 0.001 parts by weight to 20 parts by weight of the surfactant, preferably 0.01 parts by weight to 10 parts by weight of the surfactant, but the present disclosure is not limited thereto.

In the present disclosure, for instance, the coloring agent may include a dye or a pigment. For instance, in one embodiment, based on 100 parts by weight of the unsaturated carbon-carbon double bond-containing polyphenylene ether resin, the resin composition of the present disclosure may further include 0.001 parts by weight to 10 parts by weight of the coloring agent, preferably 0.01 parts by weight to 5 parts by weight of the coloring agent, but the present disclosure is not limited thereto.

The main function of adding the toughening agent in the present disclosure is to improve the toughness of the resin composition. In the present disclosure, for instance, the toughening agent may include carboxyl-terminated butadiene acrylonitrile rubber (CTBN), core-shell rubber, ethylene-propylene rubber or a combination thereof, but the present disclosure is not limited thereto. For instance, in one embodiment, based on 100 parts by weight of the unsaturated carbon-carbon double bond-containing polyphenylene ether resin, the resin composition of the present disclosure may further include 1 part by weight to 20 parts by weight of the toughening agent, preferably 3 parts by weight to 10 parts by weight of the toughening agent, but the present disclosure is not limited thereto.

In the present disclosure, for instance, the solvent may be any solvent that is suitable for dissolving the resin composition of the present disclosure, including methanol, ethanol, ethylene glycol monomethyl ether, acetone, butanone (i.e., methyl ethyl ketone), methyl isobutyl ketone, cyclohexanone, N-methylpyrrolidone, toluene, xylene, methoxyethyl acetate, ethoxyethyl acetate, propoxyethyl acetate, ethyl acetate, dimethyl formamide, dimethyl acetamide, propylene glycol methyl etheracetate, or a mixed solvent thereof, but the present disclosure is not limited thereto. The amount of the solvent is intended to completely dissolve the resin and adjust the total solid content of the resin composition to a specific total solid content. For instance, in one embodiment, the amount of solvent is adjusted to a total solid content of the resin composition of 50% to 85% (weight percentage), but the present disclosure is not limited thereto.

In addition to the resin composition, the present disclosure also provides an article made from the resin composition, such as components in various electronic products, including a prepreg, a resin film, a laminate or a printed circuit board, but the present disclosure is not limited thereto.

For instance, the resin composition of the present disclosure may be made into a prepreg, which includes a reinforcement material and a layered structure disposed thereon. The layered structure is formed by heating the resin composition at a high temperature to a semi-cured state (B-stage). The baking temperature for making the prepreg may be between 100° C. and 180° C., preferably between 120° C. and 160° C. The reinforcement material may be any one of fiber material, woven fabric and non-woven fabric. The woven fabric preferably includes fiberglass fabrics. The types of the fiberglass fabrics are not particularly limited and may be various fiberglass fabrics used for printed circuit boards, such as E-glass fabric, D-glass fabric, S-glass fabric, T-glass fabric, L-glass fabric, Q-glass fabric or QL-glass fabric (a glass fabric made of Q-glass fabric and L-glass fabric); and the type of the fiberglass includes yarns and rovings, in spread form or standard form, and the end face shapes may be round or flat. The non-woven fabric preferably includes liquid crystal resin non-woven fabric, such as polyester non-woven fabric, polyurethane non-woven fabric and so on, but the present disclosure is not limited thereto. The woven fabric may also include liquid crystal resin woven fabric, such as polyester woven fabric, polyurethane woven fabric and so on, but the present disclosure is not limited thereto. The reinforcement material may increase the mechanical strength of the prepreg. In one embodiment, the reinforcement material may be optionally pre-treated by a silane coupling agent. The prepreg is subsequently heated and cured (C-stage) to form an insulating layer.

For instance, the resin composition of the present disclosure may be made into a resin film, which is prepared by heating and baking to semi-cure the resin composition. The resin composition may be selectively coated on a supporting material, which includes a liquid crystal resin film, a polytetrafluoroethylene film, a polyethylene terephthalate film (PET film), a polyimide film (PI film), a copper foil or a resin-coated copper (RCC), followed by heating and baking to a semi-cured state so as to make the resin composition into the resin film, but the present disclosure is not limited thereto.

For instance, the resin composition of the present disclosure may be made into various laminates, which include at least two metal foils and at least one insulation layer disposed between the two metal foils. The insulation layer may be made by curing the resin composition at high temperature and high pressure to C-stage, wherein a suitable curing temperature may be between 190° C. and 220° C., preferably between 200° C. and 210° C., a curing time may be 90 to 180 minutes, preferably 120 to 150 minutes, and a pressure may be between 300 psi and 550 psi, preferably between 400 psi and 550 psi. The insulation layer may be formed by curing the prepreg or the resin film to C-stage. The material of the metal foil may be copper, aluminum, nickel, platinum, silver, gold, or alloy thereof. For instance, the metal foil may be a copper foil. In a preferred embodiment, the laminate is a copper-clad laminate (CCL).

In one embodiment, the laminate may be further processed through a circuit processing to form a printed circuit board. One preparing method of the printed circuit board of the present disclosure may be as the following: a double-sided copper-clad laminate (such as product EM-827, available from Elite Electronic Material Co., Ltd.) with a thickness of 28 mil and having 1-ounce (oz) HTE (High Temperature Elongation) copper foils may be used and subject to drilling and then electroplating, so as to form an electrical conduction between the upper layer copper foil and the bottom layer copper foil. Then, the upper layer copper foil and the bottom layer copper foil are etched to form an inner layer circuit board. Then, brown oxidation and roughening processes are performed on the inner layer circuit board to form uneven structures on the surface to increase roughness. Next, a copper foil, the prepreg, the inner layer circuit board, the prepreg and a copper foil are stacked in sequence, and then heated at 190° C. to 220° C. for 90 minutes to 180 minutes by a vacuum lamination apparatus to cure the material of the insulation layer of the prepregs. Next, black oxidation, drilling, copper plating and other circuit board processes known in the field are performed on the outmost copper foil so as to obtain the printed circuit board.

For instance, in one embodiment, the article made from the resin composition in each embodiment includes a reinforcement material or a supporting material and a semi-cured or cured product obtained by heating and chemically cross-linking the resin composition.

For instance, in one embodiment, the resin composition and the article made therefrom of the present disclosure preferably have at least one of the following properties:
a difference between peeling strengths of bonding sheet and core at board center and at board edge as measured and calculated by reference to IPC-TM-650 2.4.8 of less than or equal to 0.3 lb/in, such as between 0.05 lb/in and 0.3 lb/in;
a solder floating delamination rate as measured by reference to IPC-TM-650 2.4.13.1 of 0%;
a solder ball shear as measured by a solder ball shear tester of greater than or equal to 805 gf, such as between 805 gf and 1329 gf;
no gap between the glass fabric and the resin composition as inspected by a scanning electron microscopy (SEM).

Raw materials below are used to prepare the resin compositions of Examples and Comparative Examples of the present disclosure according to the amount listed in Table 1 to Table 5 and further made into testing samples or articles.

The chemical materials used in Examples and Comparative Examples of the present disclosure are described as follows:
SA9000: (meth)acryloyl group-containing polyphenylene ether resin, available from Sabic.
OPE-2st 1200: vinylbenzyl group-terminated polyphenylene ether resin, available from Mitsubishi Gas Chemical Co., Inc.
OPE-2st 2200: vinylbenzyl group-terminated polyphenylene ether resin, available from Mitsubishi Gas Chemical Co., Inc.
Ricon 131MA5: unhydrogenated maleic anhydride-adducted polybutadiene, available from Cray Valley.
Ricon 130MA8: unhydrogenated maleic anhydride-adducted polybutadiene, available from Cray Valley.
Ricon 130MA13: unhydrogenated maleic anhydride-adducted polybutadiene, available from Cray Valley.
Ricon 131MA10: unhydrogenated maleic anhydride-adducted polybutadiene, available from Cray Valley.
Ricon 156MA17: unhydrogenated maleic anhydride-adducted polybutadiene, available from Cray Valley.
Ricon 184MA6: unhydrogenated maleic anhydride-adducted styrene-butadiene copolymer, available from Cray Valley.
P1: self-made, as described below.
P2: self-made, as described below.
P3: self-made, as described below.
P4: self-made, as described below.
P5: self-made, as described below.
P6: self-made, as described below.
P7: self-made, as described below.
P8: self-made, as described below.
P9: self-made, as described below.
P10: self-made, as described below.
BVPE: bis(vinylphenyl)ethane, available from Linchuan Chemical Co., Ltd.
TAIC: triallyl isocyanurate, available from Sartomer.
Ricon 100: styrene-butadiene copolymer, available from Cray Valley.
B1000: polybutadiene, available from Nippon Soda Co., Ltd.
B3000: polybutadiene, available from Nippon Soda Co., Ltd.
SBS-A: styrene-butadiene block copolymer, available from Nippon Soda Co., Ltd.
EA-3000: acryloyl group-terminated polybutadiene, available from Nippon Soda Co., Ltd.
X-12-1281A-ES: silane-modified styrene-butadiene copolymer, available from Shin-Etsu Chemical Co., Ltd.
JP-100: epoxy group-containing polybutadiene, available from Nippon Soda Co., Ltd.
FG1901: hydrogenated maleic anhydride-modified styrene-butadiene copolymer, available from KRATON Corporation.
25B: 2,5-dimethyl-2,5-di(tert-butyl peroxy)-3-hexyne, available from Nippon Oils & Fats.
Spherical silicon dioxide: a chemically synthesized spherical silica with a median particle size D50 of about 2.5±2 μm, which is prepared by the microemulsion method and treated by a silane coupling agent, commercially available.
Solvent: toluene and butanone where a weight ratio of toluene to butanone is 2:1, and the toluene and the butanone are commercially available. The amount of solvents is shown as “PA” in the Tables to indicate a “proper amount” to represent an amount of sol vents is adjusted so that a solid content (S/C) of the whole resin composition is 60% to 68% (S/C=60% to 68%).

### Preparation Example 1: P1

200 g of B1000, 183 g of 4-bromobenzocyclobutene, 4.5 g of palladium acetate, 30.4 g of tris(o-tolyl)phosphine, 202 g of triethylamine, and 2000 mL of mixed solvent of anhydrous acetonitrile/N,N-dimethylformamide (DMF) are added into a reactor to form a solution. The solution is evacuated and filled with nitrogen three times. Under nitrogen atmosphere, the solution is then heated and refluxed for 36 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P1.

### Preparation Example 2: P2

200 g of B3000, 183 g of 4-bromobenzocyclobutene, 4.5 g of palladium acetate, 30.4 g of tris(o-tolyl)phosphine, 202 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 48 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P2.

### Preparation Example 3: P3

450 g of Ricon 100, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P3.

### Preparation Example 4: P4

260 g of SBS-A, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/cyclohexane/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous solid P4.

### Preparation Example 5: P5

470 g of Ricon 131MA5, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 50 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P5.

### Preparation Example 6: P6

250 g of Ricon 156MA17, 183 g of 4-bromobenzocyclobutene, 6.75 g of palladium acetate, 36.48 g of tris(o-tolyl)phosphine, 202 g of triethylamine, and 3500 mL of mixed solvent of anhydrous acetonitrile/DMF are added into a reactor to form a solution. The solution is evacuated and filled with nitrogen three times. Under nitrogen atmosphere, the solution is then heated and refluxed for 60 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P6.

### Preparation Example 7: P7

455 g of Ricon 184MA6, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P7.

### Preparation Example 8: P8

200 g of EA-3000, 183 g of 4-bromobenzocyclobutene, 4.5 g of palladium acetate, 30.4 g of tris(o-tolyl)phosphine, 202 g of triethylamine, and 3000 mL of mixed solvent of anhydrous acetonitrile/DMF are added into a reactor to form a solution. The solution is evacuated and filled with nitrogen three times. Under nitrogen atmosphere, the solution is then heated and refluxed for 48 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P8.

### Preparation Example 9: P9

455 g of X-12-1281A-ES, 128.1 g of 4-bromobenzocyclobutene, 4.5 g of palladium acetate, 30.4 g of tris(o-tolyl)phosphine, 101 g of triethylamine, and 3000 mL of mixed solvent of anhydrous acetonitrile/cyclohexane/DMF are added into a reactor to form a solution. The solution is evacuated and filled with nitrogen three times. Under nitrogen atmosphere, the solution is then heated and refluxed for 72 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous solid P9.

### Preparation Example 10: P10

260 g of JP-100, 183 g of 4-bromobenzocyclobutene, 4.5 g of palladium acetate, 30.4 g of tris(o-tolyl)phosphine, 202 g of triethylamine, and 2000 mL of mixed solvent of anhydrous acetonitrile/DMF are added into a reactor to form a solution. The solution is evacuated and filled with nitrogen three times. Under nitrogen atmosphere, the solution is then heated and refluxed for 40 hours, and the conversion rate of 4-bromobenzocyclobutene is monitored by gas chromatography. Once the desired conversion rate (>50%) is achieved, the heating process is stopped. After the solution is cooled to room temperature, petroleum ether is added thereto and stirred. The solution is filtered under vacuum to remove the salts and palladium catalyst formed during the reaction to obtain a filtrate. The filtrate is then purified by column chromatography and rotary evaporation to obtain a pale yellow viscous liquid P10.

Components and property testing results of the resin composition of Examples and Comparative Examples are shown in Table 1 to Table 5 (in parts by weight):

TABLE 1
The components (in parts by weight) and the property testing
results of the resin composition of Examples E1 to E6

| Components | | E1 | E2 | E3 | E4 | E5 | E6 |
|---|---|---|---|---|---|---|---|
| Unsaturated | SA9000 | 100 | 100 | 100 | 100 | 100 | — |
| carbon-carbon | OPE-2ST-1200 | — | — | — | — | — | 100 |
| double bond- | OPE-2ST-2200 | — | — | — | — | — | — |
| containing | | | | | | | |
| polyphenylene | | | | | | | |
| ether resin | | | | | | | |
| Unhydrogenated | Ricon 131MA5 | — | — | — | — | — | 5 |
| maleic anhydride- | Ricon 130MA8 | — | — | — | — | — | — |
| modified first | Ricon 130MA13 | — | — | — | — | — | — |
| polyolefin | Ricon 131MA10 | — | — | — | — | — | — |
| | Ricon 156MA17 | — | — | — | — | — | — |
| | Ricon 184MA6 | 1 | 10 | 20 | 10 | 10 | — |
| Benzocyclobutene- | P1 | 50 | 50 | 50 | 5 | 100 | — |
| modified second | P2 | — | — | — | — | — | — |
| polyolefin | P3 | — | — | — | — | — | 20 |
| | P4 | — | — | — | — | — | — |
| | P5 | — | — | — | — | — | — |
| | P6 | — | — | — | — | — | — |
| | P7 | — | — | — | — | — | — |
| | P8 | — | | — | — | — | — |
| | P9 | — | — | — | — | — | — |
| | P10 | — | — | — | — | — | — |
| Ricon 100 | | — | — | — | — | — | — |
| B-1000 | | — | — | — | — | — | — |
| FG1901 | | — | — | — | — | — | — |
| Crosslinking agent | BVPE | — | — | — | — | — | — |
| | TAIC | — | — | — | — | — | — |
| Curing accelerator | 25B | 0.6 | 0.6 | 0.6 | 0.6 | 0.6 | 0.1 |
| Inorganic filler | Spherical SiO₂ | 180 | 180 | 180 | 180 | 180 | 75 |
| Solvent | toluene:butanone = | PA | PA | PA | PA | PA | PA |
| | 2:1 | | | | | | |
| Properties | Unit | E1 | E2 | E3 | E4 | E5 | E6 |
| Difference between | lb/in | 0.28 | 0.17 | 0.26 | 0.29 | 0.30 | 0.26 |
| peeling strengths of | | | | | | | |
| bonding sheet and | | | | | | | |
| core at board center | | | | | | | |
| and at board edge | | | | | | | |
| Solder ball shear | gf | 812 | 1088 | 935 | 823 | 805 | 1006 |
| Bonding gap | / | OK | OK | OK | OK | OK | OK |
| Solder floating | % | 0 | 0 | 0 | 0 | 0 | 0 |
| delamination rate | | | | | | | |

TABLE 2
The components (in parts by weight) and the property testing
results of the resin composition of Examples E7 to E12

| Components | | E7 | E8 | E9 | E10 | E11 | E12 |
|---|---|---|---|---|---|---|---|
| Unsaturated | SA9000 | — | 100 | 100 | 100 | 100 | 100 |
| carbon-carbon | OPE-2ST-1200 | — | — | — | — | — | — |
| double bond- | OPE-2ST-2200 | 100 | — | — | — | — | — |
| containing | | | | | | | |
| polyphenylene | | | | | | | |
| ether resin | | | | | | | |
| Unhydrogenated | Ricon 131MA5 | — | — | — | — | — | — |
| maleic anhydride- | Ricon 130MA8 | 10 | — | — | — | — | — |
| modified first | Ricon 130MA13 | — | 8 | — | — | — | — |
| polyolefin | Ricon 131MA10 | — | — | — | — | — | — |
| | Ricon 156MA17 | — | — | 12 | — | — | — |
| | Ricon 184MA6 | — | — | — | 10 | 10 | 10 |
| Benzocyclobutene- | P1 | — | — | — | 48 | 35 | 25 |
| modified second | P2 | — | — | — | — | — | — |
| polyolefin | P3 | — | — | — | — | — | — |
| | P4 | 40 | — | — | — | — | — |
| | P5 | — | 60 | — | — | — | — |
| | P6 | — | — | — | — | — | — |
| | P7 | — | — | 80 | 2 | 15 | 25 |
| | P8 | — | — | — | — | — | — |
| | P9 | — | — | — | — | — | — |
| | P10 | — | — | — | — | — | — |
| Ricon 100 | | — | — | — | — | — | — |
| B-1000 | | — | — | — | — | — | — |
| FG1901 | | — | — | — | — | — | — |
| Crosslinking agent | BVPE | — | — | — | — | — | — |
| | TAIC | — | — | — | — | — | — |
| Curing accelerator | 25B | 1.2 | 0.6 | 0.6 | 0.6 | 0.6 | 0.6 |
| Inorganic filler | Spherical SiO₂ | 120 | 220 | 300 | 180 | 180 | 180 |
| Solvent | toluene:butanone = | PA | PA | PA | PA | PA | PA |
| | 2:1 | | | | | | |
| Properties | Unit | E7 | E8 | E9 | E10 | E11 | E12 |
| Difference between | lb/in | 0.23 | 0.20 | 0.21 | 0.14 | 0.12 | 0.08 |
| peeling strengths of | | | | | | | |
| bonding sheet and | | | | | | | |
| core at board center | | | | | | | |
| and at board edge | | | | | | | |
| Solder ball shear | gf | 1065 | 1101 | 1076 | 1198 | 1249 | 1305 |
| Bonding gap | / | OK | OK | OK | OK | OK | OK |
| Solder floating | % | 0 | 0 | 0 | 0 | 0 | 0 |
| delamination rate | | | | | | | |

TABLE 3
The components (in parts by weight) and the property testing
results of the resin composition of Examples E13 to E18

| Components | | E13 | E14 | E15 | E16 | E17 | E18 |
|---|---|---|---|---|---|---|---|
| Unsaturated | SA9000 | 100 | 100 | 100 | 80 | 50 | 40 |
| carbon-carbon | OPE-2ST-1200 | — | — | — | 10 | 15 | 40 |
| double bond- | OPE-2ST-2200 | — | — | — | 10 | 35 | 20 |
| containing | | | | | | | |
| polyphenylene | | | | | | | |
| ether resin | | | | | | | |
| Unhydrogenated | Ricon 131MA5 | — | — | — | 2 | — | — |
| maleic anhydride- | Ricon 130MA8 | — | — | — | 2 | 3 | 10 |
| modified first | Ricon 130MA13 | — | — | — | 10 | 2 | — |
| polyolefin | Ricon 131MA10 | — | 10 | — | — | 3 | 2 |
| | Ricon 156MA17 | — | — | 5 | — | 2 | — |
| | Ricon 184MA6 | 10 | — | — | 6 | — | — |
| Benzocyclobutene- | P1 | 20 | — | — | 30 | 10 | 5 |
| modified second | P2 | — | — | — | — | 10 | 25 |
| polyolefin | P3 | — | 30 | — | — | — | 3 |
| | P4 | — | — | 40 | 10 | 20 | 2 |
| | P5 | — | — | 10 | 5 | — | 3 |
| | P6 | — | 20 | — | — | 5 | — |
| | P7 | 30 | — | — | 5 | — | 10 |
| | P8 | — | — | — | — | 3 | — |
| | P9 | — | — | — | — | — | 1 |
| | P10 | — | — | — | — | 2 | 1 |
| Ricon 100 | | — | — | — | — | — | — |
| B-1000 | | — | — | — | — | — | — |
| FG1901 | | — | — | — | — | — | — |
| Crosslinking agent | BVPE | — | — | — | 15 | 10 | — |
| | TAIC | — | — | — | — | 5 | 10 |
| Curing accelerator | 25B | 0.6 | 0.6 | 1.5 | 0.6 | 0.6 | 0.3 |
| Inorganic filler | Spherical SiO₂ | 180 | 180 | 180 | 200 | 180 | 150 |
| Solvent | toluene:butanone = | PA | PA | PA | PA | PA | PA |
| | 2:1 | | | | | | |
| Properties | Unit | E13 | E14 | E15 | E16 | E17 | E18 |
| Difference between | lb/in | 0.09 | 0.07 | 0.08 | 0.06 | 0.08 | 0.05 |
| peeling strengths of | | | | | | | |
| bonding sheet and | | | | | | | |
| core at board center | | | | | | | |
| and at board edge | | | | | | | |
| Solder ball shear | gf | 1289 | 1302 | 1295 | 1306 | 1329 | 1315 |
| Bonding gap | / | OK | OK | OK | OK | OK | OK |
| Solder floating | % | 0 | 0 | 0 | 0 | 0 | 0 |
| delamination rate | | | | | | | |

TABLE 4
The components (in parts by weight) and the property testing results
of the resin composition of Comparative Examples C1 to C6

| Components | | C1 | C2 | C3 | C4 | C5 | C6 |
|---|---|---|---|---|---|---|---|
| Unsaturated | SA9000 | 100 | 100 | 100 | 100 | 0 | 100 |
| carbon-carbon | OPE-2ST-1200 | — | — | — | — | — | — |
| double bond- | OPE-2ST-2200 | — | — | — | — | — | — |
| containing | | | | | | | |
| polyphenylene | | | | | | | |
| ether resin | | | | | | | |
| Unhydrogenated | Ricon 131MA5 | — | — | — | — | — | — |
| maleic anhydride- | Ricon 130MA8 | — | — | — | — | — | — |
| modified first | Ricon 130MA13 | — | — | — | — | — | — |
| polyolefin | Ricon 131MA10 | — | — | — | — | — | — |
| | Ricon 156MA17 | — | — | — | — | — | — |
| | Ricon 184MA6 | 25 | 0 | 10 | 10 | 10 | 0 |
| Benzocyclobutene- | P1 | 50 | 50 | 0 | 110 | 50 | 50 |
| modified second | P2 | — | — | — | — | — | — |
| polyolefin | P3 | — | — | — | — | — | — |
| | P4 | — | — | — | — | — | — |
| | P5 | — | — | — | — | — | — |
| | P6 | — | — | — | — | — | — |
| | P7 | — | — | — | — | — | — |
| | P8 | — | — | — | — | — | — |
| | P9 | — | — | — | — | — | — |
| | P10 | — | — | — | — | — | — |
| Ricon 100 | | | — | — | — | — | — |
| B-1000 | | | — | — | — | — | — |
| FG1901 | | | — | — | — | — | 10 |
| Crosslinking agent | BVPE | — | — | — | — | — | — |
| | TAIC | — | — | — | — | — | — |
| Curing accelerator | 25B | 0.6 | 0.6 | 0.6 | 0.6 | 0.6 | 0.6 |
| Inorganic filler | Spherical SiO₂ | 180 | 180 | 180 | 180 | 180 | 180 |
| Solvent | toluene:butanone = | PA | PA | PA | PA | PA | PA |
| | 2:1 | | | | | | |
| Properties | Unit | C1 | C2 | C3 | C4 | C5 | C6 |
| Difference between | lb/in | 0.32 | 0.48 | 0.34 | 0.35 | 0.46 | 0.32 |
| peeling strengths of | | | | | | | |
| bonding sheet and | | | | | | | |
| core at board center | | | | | | | |
| and at board edge | | | | | | | |
| Solder ball shear | gf | 778 | 651 | 631 | 784 | 535 | 793 |
| Bonding gap | / | OK | NG | OK | OK | NG | NG |
| Solder floating | % | 8 | 10 | 47 | 5 | 100 | 3 |
| delamination rate | | | | | | | |

TABLE 5
The components (in parts by weight) and the property testing results
of the resin composition of Comparative Examples C7 to C9

| Components | | C7 | C8 | C9 |
|---|---|---|---|---|
| Unsaturated | SA9000 | 100 | 100 | 100 |
| carbon-carbon | OPE-2ST-1200 | — | — | — |
| double bond- | OPE-2ST-2200 | — | — | — |
| containing | | | | |
| polyphenylene | | | | |
| ether resin | | | | |
| Unhydrogenated | Ricon 131MA5 | — | — | — |
| maleic anhydride- | Ricon 130MA8 | — | — | — |
| modified first | Ricon 130MA13 | — | — | — |
| polyolefin | Ricon 131MA10 | — | — | — |
| | Ricon 156MA17 | — | — | — |
| | Ricon 184MA6 | 0 | 10 | 10 |
| Benzocyclobutene- | P1 | 50 | 0 | 0 |
| modified second | P2 | — | — | — |
| polyolefin | P3 | — | — | — |
| | P4 | — | — | — |
| | P5 | — | — | — |
| | P6 | — | — | — |
| | P7 | — | — | — |
| | P8 | — | — | — |
| | P9 | — | — | — |
| | P10 | — | — | — |
| Ricon 100 | | 10 | 50 | — |
| B-1000 | | — | — | 50 |
| FG1901 | | — | — | — |
| Crosslinking agent | BVPE | — | — | — |
| | TAIC | — | — | — |
| Curing accelerator | 25B | 0.6 | 0.6 | 0.6 |
| Inorganic filler | Spherical SiO₂ | 180 | 180 | 180 |
| Solvent | toluene:butanone = | PA | PA | PA |
| | 2:1 | | | |
| Properties | Unit | C7 | C8 | C9 |
| Difference between | lb/in | 0.41 | 0.33 | 0.35 |
| peeling strengths of | | | | |
| bonding sheet and | | | | |
| core at board center | | | | |
| and at board edge | | | | |
| Solder ball shear | gf | 702 | 762 | 715 |
| Bonding gap | / | OK | OK | OK |
| Solder floating | % | 0 | 23 | 32 |
| delamination rate | | | | |

Preparation of prepreg (PP, also referred as bonding sheet)

The resin compositions from each Example and each Comparative Example are individually well-mixed to form a varnish. The varnish is loaded into an impregnation tank, and a fiberglass fabric (e.g., 2116 or 1078 L-glass fiber fabric, available from Asahi) is immersed into the impregnation tank to adhere the resin composition onto the fiberglass fabric, followed by heating at 130° C. to 160° C. to a semi-cured state (B-stage), thereby obtaining a prepreg. The resin content of the prepreg made of 1078 L-glass fiber fabric is about 67%; the resin content of the prepreg made of 2116 L-glass fiber fabric is about 55%.

The property testing methods and analysis items of the Examples and Comparative Examples of the present disclosure are as follows:
1. Difference between peeling strength of bonding sheet and core at board center and at board edge

### (1) Preparation of Copper-Free Inner Laminate (Core)

Two hyper very low profile (HVLP) copper foils with a thickness of 18 μm and eight Prepregs obtained from 2116 L-glass fiber fabrics impregnated with samples of each of Examples and Comparative Examples are prepared. They are stacked in an order of one HVLP copper foil, eight Prepregs and one HVLP copper foil, followed by lamination under vacuum at 500 psi and 200° C. for 2 hours to form Copper-clad inner laminate I. Each copper-clad inner laminate I is etched to remove the copper foils on the two sides to obtain a Copper-free inner laminate I.

### (2) Preparation of Evaluation Laminate

Two high-temperature elongation (HTE) copper foils with a thickness of 18 μm, two Prepregs obtained from 2116 L-glass fiber fabrics impregnated with samples of each of Examples and Comparative Examples, and one Copper-free inner laminate I are prepared. They are stacked in an order of one HTE copper foil, one Prepreg, one Copper-free inner laminate I, one Prepreg and one HTE copper foil, followed by lamination under vacuum at 500 psi and 200° C. for 2 hours to form Evaluation laminate I.

### (3) Measurement of the Difference Between the Peeling Strengths of Bonding Sheet and Core at Board Center and at Board Edge

Three specimens of 0.5 inches×5 inches are cut from both of the edge and central regions of the Evaluation laminate I. A universal testing machine is used for measurement by reference to IPC-TM-650 2.4.8. During the process, the surface copper foil is not etched, and the test position is the interface between the Prepreg and the Copper-free inner laminate I. The interfacial peeling strengths between the Prepreg and the Copper-free inner laminate I are measured, and the results are expressed in lb/in. The average interfacial peeling strength of the three central region specimens between the Prepreg and the Copper-free inner laminate I, for both sides, is denoted as F1. Similarly, the average interfacial peeling strength of the three edge region specimens between the Prepreg and the Copper-free inner laminate I, for both sides, is denoted as F2. The difference between the peeling strengths of bonding sheet and core at board center and at board edge is calculated as the absolute value of F1-F2. A smaller difference between the peeling strengths of bonding sheet and core at board center and at board edge indicates better peeling strength stability of bonding sheet and core.
2. Solder ball shear

### (1) Preparation of Copper-Clad Inner Laminate

The Copper-clad inner laminate is the same as the Copper-clad inner laminate I above.

### (2) Preparation of Evaluation Laminate

Both sides of the Copper-clad inner laminate I are subjected to a brown oxidation. After the brown oxidation, a Prepreg made from the resin composition of the Examples or Comparative Examples and 1078 L-glass fiber fabric is laminated on each side of the Copper-clad inner laminate. On the surfaces of the two Prepregs, a 35 μm HTE copper foil is then laminated, followed by lamination under vacuum at 500 psi and 200° C. for 2 hours to form a four-layer board. Subsequently, the four-layer board is subjected to an outer-layer circuit fabrication and a solder mask forming to form Evaluation laminate II. The diameter of the pad on the Evaluation laminate II is 0.5 mm

### (3) Measurement of the Solder Ball Shear

On the pad of the Evaluation laminate II, a solder ball is implanted on both sides thereof. A solder ball shear tester was used to measure the shear strength of the solder balls on both sides thereof, and the results are expressed in gf. The shear blade width is set to 0.05 inches. The average of the solder ball shear on both sides thereof is taken as the solder ball shear strength for each Evaluation laminate II. A higher solder ball shear indicates stronger adhesion between the laminate and the solder ball, representing better solderability.
3. Bonding gap

Sections of the Copper-free inner laminate I are prepared and inspected under a scanning electron microscope (SEM) to examine the interface between the glass fiber fabric and the resin composition for the presence of gaps. If no gaps are inspected, the result is recorded as “OK”; if gaps are present, the result is recorded as “NG”. The absence of gaps is preferable.
4. Solder floating delamination rate

### Preparation of Copper-Free Inner Laminate II

Two hyper very low profile (HVLP) copper foils with a thickness of 18 μm and two Prepregs obtained from 2116 L-glass fiber fabrics impregnated with samples of each of Examples and Comparative Examples are prepared. They are stacked in an order of one HVLP copper foil, two Prepregs and one HVLP copper foil, followed by lamination under vacuum at 500 psi and 200° C. for 2 hours to form Copper-clad inner laminate II. Each copper-clad inner laminate II is etched to remove the copper foils on the two sides to obtain a Copper-free inner laminate II.

### (2) Preparation of Evaluation Laminate

Eight Prepregs obtained from 1078 L-glass fiber fabrics impregnated with samples of each of Examples and Comparative Examples, and three Copper-free inner laminate II are prepared. They are stacked alternately in an order of one Copper-free inner laminate II and two Prepreg, and a HVLP copper foil with a thickness of 18 μm is stacked on each of the outermost surfaces, followed by lamination under vacuum at 500 psi and 200° C. for 2 hours to form an eight-layer board. The eight-layer board is drilled and electroplated to form Evaluation laminate III.

### (3) Measurement of the Solder Floating Delamination Rate

The Evaluation laminate III is cut into 6 specimens of 2.2 inches×5.9 inches. Each specimen is placed in a 288° C. tin bath for 10 seconds to undergo solder floating, then removed and cooled for 30 seconds, and this process is repeated 20 times. The specimen is then sliced and inspected under an optical microscope to check for any delamination. The solder floating delamination rate is calculated as: solder floating delamination rate=(number of delaminated holes×100%)/total number of holes. A lower solder floating delamination rate is preferable. The term “delamination” refers to interlayer peeling off or bubbling phenomena, which may occur between any layers of the laminate. For instance, peeling off between insulation layers is referred to as delamination, and bubbling and separation between the copper foil and the insulation layer can also be referred to as delamination.

By referring to the property testing results in Table 1 to Table 5, the following phenomena can be clearly observed:

According to Examples E1 to E18, it can be confirmed that the resin composition of the present disclosure and the article made therefrom may have improvements in one or more properties including stability of peeling strength of bonding sheet and core, solder ball shear, bonding gap, solder floating delamination rate.

The benzocyclobutene-modified second polyolefin contained in Examples E1˜E9 is any one of benzocyclobutene-modified heteroatom-containing polyolefin or benzocyclobutene-modified non-heteroatom-containing polyolefin, and the benzocyclobutene-modified second polyolefin contained in Examples E10 to E18 is a combination of benzocyclobutene-modified heteroatom-containing polyolefin and benzocyclobutene-modified non-heteroatom-containing polyolefin. Compared to the resin composition containing only benzocyclobutene-modified heteroatom-containing polyolefin or benzocyclobutene-modified non-heteroatom-containing polyolefin and the article made therefrom, the resin composition containing the combination of benzocyclobutene-modified heteroatom-containing polyolefin and benzocyclobutene-modified non-heteroatom-containing polyolefin and the article made therefrom have significant improvements in at least two properties including stability of peeling strength of bonding sheet and core, and solder ball shear.

According to the comparison of Examples E1 to E18 and Comparative Examples C1 to C2, it can be confirmed that with respect to 100 parts by weight of the unsaturated carbon-carbon double bond-containing polyphenylene ether resin, if the amount of the unhydrogenated maleic anhydride-modified first polyolefin is not within a range of 1 to 20 parts by weight, the resin composition and the article made therefrom have significant deterioration in at least three properties including stability of peeling strength of bonding sheet and core, solder ball shear and solder floating delamination rate.

According to the comparison of Examples E1 to E18 and Comparative Examples C3 to C4, it can be confirmed that with respect to 100 parts by weight of the unsaturated carbon-carbon double bond-containing polyphenylene ether resin, if the amount of the benzocyclobutene-modified second polyolefin is not within a range of 5 to 100 parts by weight, the resin composition and the article made therefrom have significant deterioration in at least three properties including stability of peeling strength of bonding sheet and core, solder ball shear and solder floating delamination rate.

According to the comparison of Examples E1 to E18 and Comparative Examples C2, C3 and C5, it can be confirmed that if the resin composition does not have unsaturated carbon-carbon double bond-containing polyphenylene ether resin, unhydrogenated maleic anhydride-modified first polyolefin and benzocyclobutene-modified second polyolefin at the same time, the article made therefrom have significant deterioration in at least three properties including stability of peeling strength of bonding sheet and core, solder ball shear and solder floating delamination rate.

According to the comparison of Examples E1 to E18 and Comparative Examples C6 to C7, it can be confirmed that compared to the resin composition containing unmodified polyolefin (Ricon 100) or hydrogenated maleic anhydride-modified polyolefin (FG1901) and the article made therefrom, the resin composition containing unhydrogenated maleic anhydride-modified first polyolefin of the present disclosure and the article made therefrom have significant improvements in at least two properties including stability of peeling strength of bonding sheet and core, and solder ball shear.

According to the comparison of Examples E1 to E18 and Comparative Examples C8 to C9, it can be confirmed that compared to the resin composition containing unmodified polyolefin (Ricon 100 or B-1000) and the article made therefrom, the resin composition containing the benzocyclobutene-modified second polyolefin of the present disclosure and the article made therefrom have significant improvements in at least three properties including stability of peeling strength of bonding sheet and core, solder ball shear and solder floating delamination rate.

The above embodiments are provided only for illustrative purposes and are not intended to limit the present disclosure or its applications. In the present disclosure, terms such as “embodiment” are to be understood as “an example or illustration.” Unless otherwise specified, any exemplary embodiment described herein should not be considered superior to other forms of implementation. Although at least one exemplary embodiment or comparative example has been provided in the foregoing descriptions, it should be understood that various modifications to the present disclosure are possible. The scope of the present disclosure is not limited to the disclosed embodiments. Therefore, it will be apparent to person skilled in the art that simple modifications to the exemplary embodiments of the present disclosure fall within the scope of the technical spirit of the present disclosure.

What is claimed is:

1. A resin composition, comprising:
a component (A): 100 parts by weight of an unsaturated carbon-carbon double bond-containing polyphenylene ether resin;
a component (B): 1 to 20 parts by weight of an unhydrogenated maleic anhydride-modified first polyolefin; and
a component (C): 5 to 100 parts by weight of a benzocyclobutene-modified second polyolefin.

2. The resin composition of claim 1, wherein the unsaturated carbon-carbon double bond-containing polyphenylene ether resin comprises any one of a vinylbenzyl group-containing polyphenylene ether resin, a (meth)acryloyl group-containing polyphenylene ether resin, a vinyl group-containing polyphenylene ether resin, an allyl group-containing polyphenylene ether resin or a combination thereof.

3. The resin composition of claim 1, wherein the unhydrogenated maleic anhydride-modified first polyolefin comprises any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer or a combination thereof.

4. The resin composition of claim 1, wherein the benzocyclobutene-modified second polyolefin comprises any one of a benzocyclobutene-modified heteroatom-containing polyolefin, a benzocyclobutene-modified non-heteroatom-containing polyolefin or a combination thereof.

5. The resin composition of claim 4, wherein the heteroatom-containing polyolefin comprises any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer, a vinyl-polybutadiene-urethane polymer, a silane-modified styrene-butadiene copolymer, an acryloyl group-terminated polybutadiene, an epoxy group-containing polybutadiene or a combination thereof.

6. The resin composition of claim 4, wherein the non-heteroatom-containing polyolefin comprises any one of a polybutadiene, a polyisoprene, a styrene-butadiene copolymer, a styrene-isoprene copolymer, a styrene-butadiene-divinylbenzene polymer, a styrene-ethylene-divinylbenzene polymer, a styrene-ethylvinylbenzene-divinylbenzene polymer or a combination thereof.

7. The resin composition of claim 4, wherein a mass ratio of the benzocyclobutene-modified non-heteroatom-containing polyolefin to the benzocyclobutene-modified heteroatom-containing polyolefin is 2:3 to 24:1.

8. The resin composition of claim 1, wherein the resin composition further comprises an unsaturated carbon-carbon double bond-containing crosslinking agent, and the unsaturated carbon-carbon double bond-containing crosslinking agent is any one of a bis(vinylphenyl)ethane, a divinylbenzene, a divinylnaphthalene, a divinylbiphenyl, a triallyl isocyanurate, a triallyl cyanurate, a vinylbenzocyclobutene, a bis(vinylbenzyl)ether, a trivinyl cyclohexane, a diallyl bisphenol A, a butadiene, a decadiene, an octadiene or a combination thereof.

9. The resin composition of claim 1, wherein the resin composition further comprises any one of a polyolefin different from the component (B) and the component (C), an organosilicon resin, a benzoxazine resin, an epoxy resin, a polyester resin, a phenol resin, an amine curing agent, a polyamide, a polyimide, a styrene maleic anhydride, a maleimide resin, a cyanate ester resin, a maleimide triazine resin or a combination thereof.

10. The resin composition of claim 1, wherein the resin composition further comprises a curing accelerator, a polymerization inhibitor, a flame retardant, an inorganic filler, a surfactant, a coloring agent, a toughening agent, a solvent or a combination thereof.

11. An article made from the resin composition of claim 1, comprising: a prepreg, a resin film, a laminate or a printed circuit board.

12. The article of claim 11, wherein the article has at least one of the following properties:
a difference between peeling strengths of bonding sheet and core at board center and at board edge as measured and calculated by reference to IPC-TM-650 2.4.8 of less than or equal to 0.3 lb/in;
a solder floating delamination rate as measured by reference to IPC-TM-650 2.4.13.1 of 0%;
a solder ball shear as measured by a solder ball shear tester of greater than or equal to 805 gf;
no gap between a glass fabric and a resin composition as inspected by a scanning electron microscopy (SEM).
